(19) United States
(12) Patent Application Publication
(10) Pub. No.: US 2025/0010364 A1
(43) Pub. Date: Jan. 9, 2025

(54) Amorphous Alloy Soft Magnetic Powder And Method For Manufacturing Amorphous Alloy Soft Magnetic Powder

(71) Applicant: SEIKO EPSON CORPORATION, Tokyo (JP)

(72) Inventors: Takuma ENOMOTO, Hachinohe (JP); Junya ABE, Hachinohe (JP); Kai KITAMURA, Hachinohe (JP); Hiroyoshi OTAKA, Hachinohe (JP)

(21) Appl. No.: 18/393,822

(22) Filed: Dec. 22, 2023

(30) Foreign Application Priority Data
Dec. 26, 2022 (JP) 2022-207952

(51) Int. Cl. B22F 1/08; B22F 1/05; C22C 45/02; H01F 1/153

(52) U.S. Cl. CPC B22F 1/08; B22F 1/05; C22C 45/02; H01F 1/153; B22F 2304/10; B22F 2999/00; C22C 2200/02; C22C 2202/02

(57) ABSTRACT

An amorphous alloy soft magnetic powder contains a particle having a flat shape, has a volume-based average particle diameter of more than 150 μm and 500 μm or less measured by a laser diffraction and scattering particle size distribution analyzer, and has a coercive force of 398 A/m or less, i.e., 5.0 Oe or less. A proportion of particles having a particle diameter of more than 300 μm and 600 μm or less classified by sieving may be 15 mass % or more and 40 mass % or less.

The present application is based on, and claims priority from JP Application Serial Number 2022-207952, filed Dec. 26, 2022, the disclosure of which is hereby incorporated by reference herein in its entirety.

### BACKGROUND

### 1. Technical Field

The present disclosure relates to an amorphous alloy soft magnetic powder and a method for manufacturing an amorphous alloy soft magnetic powder.

### 2. Related Art

When an electromagnetic wave noise occurs inside an electronic device or between electronic devices, the electronic device may malfunction. Therefore, in the electronic device, an electromagnetic wave noise suppression sheet that absorbs the electromagnetic wave noise is used.

The electromagnetic wave noise suppression sheet is, for example, a sheet molded using a soft magnetic metal powder as a filler and an organic binder. By flattening the soft magnetic metal powder, a demagnetizing field coefficient can be reduced, a magnetic permeability of the electromagnetic wave noise suppression sheet can be increased, and high saturation magnetization can be obtained. Accordingly, an electromagnetic wave noise suppression sheet that can be used up to a high frequency range is obtained.

JP-A-10-212503 discloses an amorphous soft magnetic alloy powder containing flat particles having a particle diameter of 149 μm to 210 μm and an aspect ratio of 3 to 5. JP-A-10-212503 also discloses manufacturing of this amorphous soft magnetic alloy powder by a high-speed rotating water flow method. Specifically, the high-speed rotating water flow method is a method to obtain a metal powder by forming a cooling water layer that flows down while swirling on an inner circumferential surface of a cooling tubular body, and supplying a jet flow of a molten metal flow to the cooling water layer to cause the molten metal to be divided and rapidly solidified.

However, the amorphous soft magnetic alloy powder disclosed in JP-A-10-212503 has a relatively small particle diameter. When the particle diameter is small, it is difficult to increase a coverage of particles per unit area when a sheet is prepared. Therefore, when the particle diameter is small, it is necessary to increase the coverage by adding the amorphous soft magnetic alloy powder at a high concentration. On the other hand, the demagnetizing field coefficient decreases as the aspect ratio of the particle increases. Therefore, in order to increase the coverage without adding the amorphous soft magnetic alloy powder at a high concentration and to increase a magnetic permeability of the sheet, it is required to further increase the particle diameter of the amorphous soft magnetic alloy powder.

### SUMMARY

An amorphous alloy soft magnetic powder according to an application example of the present disclosure containing:
a particle having a flat shape, in which
the amorphous alloy soft magnetic powder has a volume-based average particle diameter of more than 150 μm and 500 μm or less measured by a laser diffraction and scattering particle size distribution analyzer, and a coercive force of 398 A/m or less, i.e., 5.0 Oe or less.

A method for manufacturing an amorphous alloy soft magnetic powder according to an application example of the present disclosure using a device including
a molten metal supply portion that causes a molten metal to flow down,
a tubular body provided below the molten metal supply portion, and
a coolant outflow portion that causes a coolant to flow out along an inner circumferential surface of the tubular body to form a swirling flow,
the method for manufacturing an amorphous alloy soft magnetic powder including:
causing the molten metal to flow down from the molten metal supply portion while narrowing the molten metal to a diameter of 1 mm or more and 10 mm or less; and
causing the molten metal that flows down to enter the swirling flow at a speed of 50 m/sec or more and 150 m/sec or less without being scattered by gas to obtain an amorphous alloy soft magnetic powder, in which
the amorphous alloy soft magnetic powder,
contains a particle having a flat shape,
has a volume-based average particle diameter of more than 150 μm and 500 μm or less measured by a laser diffraction and scattering particle size distribution analyzer, and
has a coercive force of 398 A/m or less, i.e., 5.0 Oe or less.

### BRIEF DESCRIPTION OF THE DRAWINGS

FIG. 1 is an enlarged observed image showing an amorphous alloy soft magnetic powder according to an embodiment.

FIG. 2 is a cross-sectional view showing an example of a configuration of an electromagnetic wave suppressor.

FIG. 3 is a cross-sectional view showing an example of a powder manufacturing device used in a method for manufacturing an amorphous alloy soft magnetic powder according to the embodiment.

FIG. 4 is a flowchart showing a configuration of the method for manufacturing an amorphous alloy soft magnetic powder according to the embodiment.

FIG. 5 is a cross-sectional view showing a powder manufacturing device in the related art.

### DESCRIPTION OF EMBODIMENTS

Hereinafter, an amorphous alloy soft magnetic powder and a method for manufacturing an amorphous alloy soft magnetic powder according to the present disclosure will be described in detail based on an embodiment shown in the accompanying drawings.

### 1. Amorphous Alloy Soft Magnetic Powder

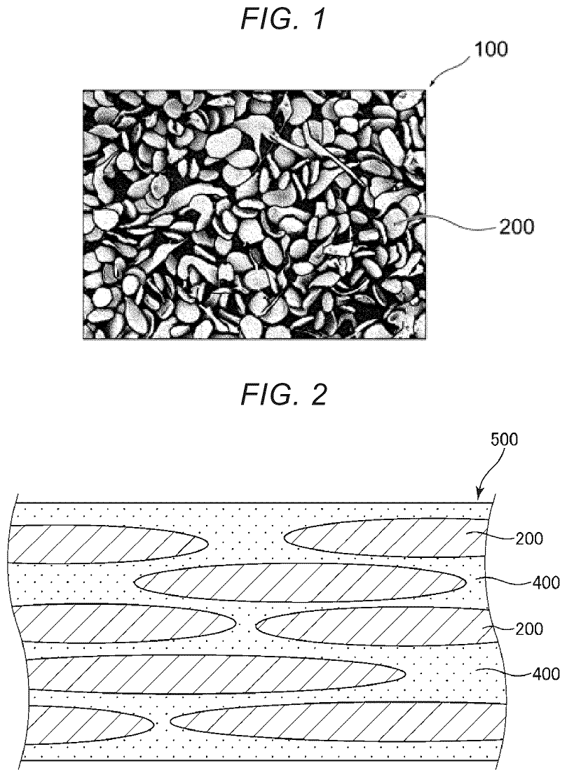

FIG. 1 is an enlarged observed image showing an amorphous alloy soft magnetic powder 100 according to an embodiment.

The amorphous alloy soft magnetic powder 100 shown in FIG. 1 contains flat particles 200. The flat particle 200 is a scale-shaped particle, specifically, has a shape having two main surfaces having a front and back relationship with each other and a thickness sufficiently thinner than a maximum length in the main surface. The amorphous alloy soft magnetic powder 100 has a volume-based average particle diameter D of more than 150 μm and 500 μm or less measured by a laser diffraction and scattering particle size distribution analyzer. Further, the amorphous alloy soft magnetic powder 100 has a coercive force of 398 A/m or less (5.0 Oe or less).

Such an amorphous alloy soft magnetic powder 100 contains the flat particle 200 having a large particle diameter and a low coercive force. Therefore, when molded into a sheet shape together with a binding agent, a coverage of the particles per unit area can be increased. As a result, by using the amorphous alloy soft magnetic powder 100, a sheet-shaped molded product having a high coverage can be obtained without adding the amorphous alloy soft magnetic powder 100 at a high concentration. Accordingly, the amorphous alloy soft magnetic powder 100 that can be used to manufacture an electromagnetic wave suppressor having excellent mechanical properties is obtained.

Since the flat particle 200 has a small demagnetizing field coefficient, a magnetic permeability of the molded product can be increased. Therefore, by using the amorphous alloy soft magnetic powder 100, it is possible to obtain an electromagnetic wave suppressor having excellent properties of suppressing electromagnetic waves and having excellent mechanical properties.

The term “electromagnetic wave suppressor” in the specification is a general term for a radio wave shield, a radio wave absorber, and a magnetic shield. The radio wave shield is a member that suppresses entry of radio waves and emission of radio waves to an outside. The radio wave absorber is a member that suppresses external radio waves and emitted radio waves by absorbing the radio waves. The magnetic shield is a member that bypasses magnetism by inducing magnetism inside. Such an electromagnetic wave suppressor has, for example, a sheet shape or a box shape, and covers an electromagnetic wave generation source or an object to be protected. Therefore, the amorphous alloy soft magnetic powder 100 is required to have good properties when being kneaded together with a binding agent and molded into sheet shape (plate shape). In the specification, properties of reflecting or absorbing radio waves or bypassing magnetism are referred to as properties of suppressing electromagnetic waves.

### 1.1. Shape of Particle

The flat particle 200 has a flat shape. The flat shape means that an average thickness T of the flat particles 200 is sufficiently small with respect to the average particle diameter D of the amorphous alloy soft magnetic powder 100.

The average particle diameter D of the amorphous alloy soft magnetic powder 100 is a 50% particle diameter of a volume-based particle size distribution measured by the laser diffraction and scattering particle size distribution analyzer.

The average thickness T of the flat particles 200 is an average value of measured values obtained by measuring thicknesses of 100 or more flat particles 200 with a scanning electron microscope.

Since the flat particle 200 having such a flat shape has a small demagnetizing field coefficient, a magnetic permeability of the electromagnetic wave suppressor can be increased. When the flat particle 200 is molded into a sheet shape, the flat particle 200 is easily oriented in an in-plane direction due to a shape effect. Therefore, without increasing a concentration of the amorphous alloy soft magnetic powder 100 added, it is possible to implement an electromagnetic wave suppressor having a high coverage (space factor) of the flat particles 200 and having excellent properties of suppressing electromagnetic waves.

A degree of flatness of the flat particle 200 can be quantified by an aspect ratio. The aspect ratio of the flat particle 200 can be defined by a ratio (D/T) of the average particle diameter D to the average thickness T. The aspect ratio of the flat particle 200 is 3 or more. Accordingly, the flat particle 200 is sufficiently flat. The aspect ratio of the flat particle 200 is preferably 4 or more and 100 or less, more preferably 5 or more and 80 or less, and still more preferably 7 or more and 50 or less. Accordingly, the demagnetizing field coefficient of the flat particle 200 can be sufficiently reduced, and when the amorphous alloy soft magnetic powder 100 is molded into a sheet shape, an area that can be covered with a unit amount of the flat particles 200 can be further increased. As a result, it is possible to obtain a sheet-shaped molded product having a particularly high coverage of the flat particles 200 and a high magnetic permeability while further reducing an addition amount of the amorphous alloy soft magnetic powder 100. That is, it is possible to obtain an electromagnetic wave suppressor having particularly good properties of suppressing electromagnetic waves and also having particularly good mechanical properties.

When the aspect ratio goes below the above lower limit value, the magnetic permeability of the molded product may decrease, or the coverage of the flat particles 200 may decrease. On the other hand, when the aspect ratio exceeds the above upper limit value, dispersibility of the flat particles 200 decreases, and handling of the amorphous alloy soft magnetic powder 100 becomes difficult, which may reduce the coverage of the flat particles 200 in the molded product.

### 1.2. Average Particle Diameter

The average particle diameter D of the amorphous alloy soft magnetic powder 100 is more than 150 μm and 500 μm or less, preferably 200 μm or more and 400 μm or less, and more preferably 212 μm or more and 350 μm or less. When the average particle diameter D is within the above range, the flat particle 200 is a particle having a larger main surface. Therefore, it is possible to obtain a sheet-shaped molded product having a particularly high coverage of the flat particles 200 and a high magnetic permeability while further reducing an addition amount of the amorphous alloy soft magnetic powder 100.

When the average particle diameter D goes below the above lower limit value, the coverage in the sheet-shaped molded product cannot be sufficiently increased once the amorphous alloy soft magnetic powder 100 is not added at a high concentration. Accordingly, the mechanical properties of the electromagnetic wave suppressor are decreased. On the other hand, when the average particle diameter D exceeds the above upper limit value, dispersibility of the amorphous alloy soft magnetic powder 100 decreases, and handling of the amorphous alloy soft magnetic powder 100 becomes difficult. Therefore, the coverage of the flat particles 200 in the molded product decreases.

### 1.3. Coercive Force

The coercive force of the amorphous alloy soft magnetic powder 100 is 398 A/m or less (5.0 Oe or less), preferably 239 A/m or less (3.0 Oe or less), and more preferably 159 A/m or less (2.0 Oe or less). When the coercive force is within the above range, residual magnetization of the amorphous alloy soft magnetic powder 100 also tends to be small. Therefore, by using the amorphous alloy soft magnetic powder 100 having such a coercive force, an electromagnetic wave suppressor having a particularly good properties of suppressing electromagnetic waves can be obtained.

When the coercive force exceeds the above upper limit value, the residual magnetization also increases. Therefore, the properties of the electromagnetic wave suppressor of suppressing the electromagnetic wave are decreased.

The coercive force of the amorphous alloy soft magnetic powder 100 can be measured, for example, by a vibrating sample magnetometer such as TM-VSM1230-MHHL manufactured by Tamakawa Co., Ltd.

### 1.4. Relationship Between Particle Diameter and Mass Proportion

In the amorphous alloy soft magnetic powder 100, when particles having a particle diameter of more than 300 μm and 600 μm or less are classified by sieving, a proportion of particles in this particle diameter range is preferably 15 mass % or more and 40 mass % or less, more preferably 20 mass % or more and 35 mass % or less, and still more preferably 20 mass % or more and 30 mass % or less. In the following description, particles having a particle diameter of more than 300 μm and 600 μm or less obtained by sieving and classifying the amorphous alloy soft magnetic powder 100 are referred to as “−600/+300 particles”. When a mass proportion of the −600/+300 particles is within the above range, by using the amorphous alloy soft magnetic powder 100, a sheet-shaped molded product having a particularly high coverage of the flat particles 200 and a high magnetic permeability while further reducing the addition amount can be obtained.

When the mass proportion of the −600/+300 particles goes below the above lower limit value, a particle size distribution of the amorphous alloy soft magnetic powders 100 becomes distorted, and the distribution may be extremely biased toward a small diameter side and a large diameter side. In this case, the dispersibility of the flat particles 200 may decrease, and the magnetic permeability of the molded product may decrease. On the other hand, the mass proportion of the −600/+300 particles may exceed the above upper limit value, but the coverage of the flat particles 200 may decrease.

The sieving is performed according to metallic powders-determination of particle size by dry sieving specified in JIS Z 2510:2004.

First, the amorphous alloy soft magnetic powder 100 is put into a sieve for JIS test having a nominal size of opening of 600 μm to obtain classified materials remaining on the sieve and classified materials passed through the sieve. The former classified materials are particles having a particle diameter of more than 600 μm, and the latter classified materials are particles having a particle diameter of 600 μm or less. The former classified materials are “+600 particles”, and the latter classified materials are “−600 particles”. A mass of the +600 particles is measured.

Next, the −600 particles are put into a sieve for JIS test having a nominal size of opening of 425 μm to obtain classified materials remaining on the sieve and classified materials passed through the sieve. The former classified materials are particles having a particle) diameter of more than 425 μm and 600 μm or less, and the latter classified materials are particles having a particle diameter of 425 μm or less. The former classified materials are “−600/+425 particles”, and the latter classified materials are “−425 particles”. A mass of the −600/+425 particles is measured.

Next, the −425 particles are put into a sieve for JIS test having a nominal size of opening of 300 μm to obtain classified materials remaining on the sieve and classified materials passed through the sieve. The former classified materials are particles having a particle diameter of more than 300 μm and 425 μm or less, and the latter classified materials are particles having a particle diameter of 300 μm or less. The former classified materials are “−425/+300 particles”, and the latter classified materials are “−300 particles”. A mass of the −425/+300 particles is measured.

Next, the −300 particles are put into a sieve for JIS test having a nominal size of opening of 212 μm to obtain classified materials remaining on the sieve and classified materials passed through the sieve. The former classified materials are particles having a particle diameter of more than 212 μm and 300 μm or less, and the latter classified materials are particles having a particle diameter of 212 μm or less. The former classified materials are “−300/+212 particles”, and the latter classified materials are “−212 particles”. A mass of the −300/+212 particles is measured.

Next, the −212 particles are put into a sieve for JIS test having a nominal size of opening of 150 μm to obtain classified materials remaining on the sieve and classified materials passed through the sieve. The former classified materials are particles having a particle diameter of more than 150 μm and 212 μm or less, and the latter classified materials are particles having a particle diameter of 150 μm or less. The former classified materials are “−212/+150 particles”, and the latter classified materials are “−150 particles”. A mass of the −212/+150 particles is measured.

A mass of −600/+300 particles is obtained by adding the mass of −600/+425 particles and the mass of −425/+300 particles. The mass of −600/+300 particles is divided by a total mass of the amorphous alloy soft magnetic powder 100 to obtain the mass proportion of −600/+300 particles.

### 1.5. Relationship Between Particle Diameter and Coercive Force

In the amorphous alloy soft magnetic powder 100, when particles (−600/+300 particles) having a particle diameter of more than 300 μm and 600 μm or less are classified by sieving, a coercive force of the −600/+300 particles is preferably 398 A/m or less (5.0 Oe or less), and more preferably 239 A/m or less (3.0 Oe or less). The −600/+300 particle is a particle having a relatively large particle diameter in the amorphous alloy soft magnetic powder 100. In many cases, particles having a large particle diameter are more difficult to be made amorphous than particles having a small particle diameter. Therefore, when the coercive force of the −600/+300 particles is within the above range, the coercive force of the entire amorphous alloy soft magnetic powder 100 can be sufficiently reduced.

When the coercive force of the −600/+300 particles exceeds the above upper limit value, the coercive force of the entire amorphous alloy soft magnetic powder 100 tends to increase. Therefore, the properties of the electromagnetic wave suppressor of suppressing the electromagnetic wave may be decreased.

The coercive force of the −600/+300 particles can be measured, for example, by a vibrating sample magnetometer such as TM-VSM1230-MHHL manufactured by Tamakawa Co., Ltd.

### 1.6. Relationship Between Aspect Ratio and Coercive Force

In the amorphous alloy soft magnetic powder 100, when particles (−212/+150 particles) having a particle diameter of more than 150 μm and 212 μm or less are classified by sieving, an aspect ratio of the −212/+150 particles is preferably 4 or more and 100 or less, more preferably 5 or more and 50 or less, and still more preferably 7 or more and 30 or less. When the aspect ratio of the −212/+150 particles is within the above range, the −212/+150 particles having a relatively small diameter in the amorphous alloy soft magnetic powder 100 also have a sufficiently flat shape. Therefore, since the −212/+150 particles also have a shape effect and are easily oriented in the in-plane direction, it is possible to implement an electromagnetic wave suppressor having a particularly high coverage (space factor) of the flat particles 200 without increasing the concentration of the amorphous alloy soft magnetic powder 100 added.

The aspect ratio of the −212/+150 particles can be defined by a ratio (D1/T1) of an average particle diameter D1 to an average thickness T1. The average particle diameter D1 of the −212/+150 particles is 181 μm, which is a median diameter of a particle size. The average thickness T1 is an average value of measured values obtained by measuring thicknesses of 100 or more −212/+150 particles with a scanning electron microscope.

A coercive force of the −212/+150 particles is preferably 159 A/m or less (2.0 Oe or less). When the coercive force of the −212/+150 particles is within the above range, the coercive force of the entire amorphous alloy soft magnetic powder 100 can be sufficiently decreased, and an electromagnetic wave suppressor having particularly good properties of suppressing electromagnetic waves can be implemented.

### 1.7. Composition

Examples of constituent materials for the amorphous alloy soft magnetic powder 100 include an Fe-based amorphous alloy, a Ni-based amorphous alloy, and a Co-based amorphous alloy.

Examples of the Fe-based amorphous alloy include a binary or multi-component Fe-based alloy such as Fe—Si—B—based, Fe—Si—Cr—B-based, Fe—Si—B—C-based, Fe—Si—B—Cr—C-based, Fe—Si—Cr-based, Fe—B-based, Fe—B—C-based, Fe—P—C-based, Fe—Co—Si—B-based, Fe—Si—B—Nb-based, Fe—Si—B—Nb—Cu—based, and Fe—Zr—B-based alloys.

Examples of the Ni-based amorphous alloy include Ni-based alloys such as Ni—Si—B-based and Ni—P—B-based alloys.

Examples of the Co-based amorphous alloy include Co-based alloys such as a Co—Si—B-based alloy.

The constituent material for the amorphous alloy soft magnetic powder 100 is preferably a material having a composition represented by a compositional formula (Fe₁₋ₓCrₓ)ₐ(Si_{1-y}B_{y})_{100-a-b}C_{b}(where 0<x≤0.06, 0.3≤y≤0.7, 70.0≤a≤81.0, and 0<b≤3.0) among the above materials. This compositional formula represents a ratio of the number of atoms in the composition containing five elements, which are Fe, Cr, Si, B, and C.

Fe (iron) greatly affects basic magnetic properties and mechanical properties of the amorphous alloy soft magnetic powder 100 according to the embodiment.

A content rate of Fe is set such that Fe is a main component, that is, a ratio of the number of atoms is the highest in the amorphous alloy soft magnetic powder 100. In the amorphous alloy soft magnetic powder 100, the content rate of Fe is preferably 70.0 atomic % or more and 78.0 atomic % or less, more preferably 71.0 atomic % or more and 77.0 atomic % or less, and still more preferably 72.0 atomic % or more and 75.0 atomic % or less. When the content rate of Fe goes below the above lower limit value, the magnetic permeability of the amorphous alloy soft magnetic powder 100 may decrease depending on the composition. On the other hand, when the content rate of Fe exceeds the above upper limit value, it may be difficult to stably form an amorphous structure depending on the composition.

Cr (chromium) acts to improve corrosion resistance of the amorphous alloy soft magnetic powder 100. By improving the corrosion resistance, oxidation of the particle is reduced, and decrease of magnetic properties (decrease in magnetic permeability and increase in coercive force) due to the oxidation can be suppressed.

x represents a proportion of the number of Cr atoms to a total number of atoms of the number of Fe atoms and the number of Cr atoms, i.e., 1. In the amorphous alloy soft magnetic powder 100, preferably 0<x≤0.06, more preferably 0.01≤x≤0.05, and still more preferably 0.02≤x≤0.04. When x goes below the above lower limit value, the corrosion resistance may be decreased. On the other hand, when x exceeds the above upper limit value, the magnetic properties may be decreased.

a represents a total proportion of Fe and Cr, and is preferably 70.0≤a≤81.0, more preferably 73.0≤a≤80.0, and still more preferably 75.0≤ a≤77.0. When a goes below the above lower limit value, the magnetic properties or the corrosion resistance may be decreased. On the other hand, when a exceeds the above upper limit value, the amorphous alloy soft magnetic powder 100 may be easily crystallized during manufacturing.

When the amorphous alloy soft magnetic powder 100 is manufactured from a raw material, Si (silicon) promotes amorphization and increases the magnetic permeability of the amorphous alloy soft magnetic powder 100. Accordingly, a high magnetic permeability and a low coercive force can be achieved.

B (boron) promotes amorphization when the amorphous alloy soft magnetic powder 100 is manufactured from the raw material. In particular, by using Si and B in combination, amorphization can be synergistically promoted based on a difference in an atomic radius between Si and B. Accordingly, a high magnetic permeability and a low coercive force can be sufficiently achieved.

y represents a proportion of the number of B atoms to a total number of atoms of the number of Si atoms and the number of B atoms, i.e., 1. In the amorphous alloy soft magnetic powder 100, preferably 0.3≤y≤0.7, and more preferably 0.4≤y≤0.6. Accordingly, a balance between the number of Si atoms and the number of B atoms can be optimized. When y goes below the above lower limit value or exceeds the above upper limit value, the balance between the number of Si atoms and the number of B atoms is lost. Therefore, for example, when the proportion of Fe is increased to improve the magnetic properties, amorphization may become difficult.

A content rate of Si is preferably 8.0 atomic % or more and 13.5 atomic % or less, and more preferably 10.5 atomic % or more and 12.0 atomic % or less.

A content rate of B is preferably 8.0 atomic % or more and 13.5 atomic % or less, and more preferably 10.5 atomic % or more and 12.0 atomic % or less.

C (carbon) reduces viscosity of a melt when a raw material for the amorphous alloy soft magnetic powder 100 is melted, and facilitates amorphization and flattening. Accordingly, the amorphous alloy soft magnetic powder 100 having a high aspect ratio and a high magnetic permeability can be obtained.

b represents a content rate of C, and is preferably 0<b≤3.0, more preferably 1.0≤b≤2.8, and still more preferably 1.5≤b≤2.5. When b goes below the above lower limit value, the viscosity of the melt may not be sufficiently reduced, and a shape of the particles may not be sufficiently flattened. On the other hand, when b exceeds the above upper limit value, the amorphous alloy soft magnetic powder 100 may be easily crystallized during manufacturing.

The amorphous alloy soft magnetic powder 100 may contain, in addition to the elements described above, other elements regardless of an additive element or an impurity. A total content rate of the other elements is preferably 1.0 mass % or less, more preferably 0.2 mass % or less, and still more preferably 0.1 mass % or less. When the content rate is within this range, the effect described above is hardly inhibited, so that containing of the other elements is acceptable.

The above composition and impurity are identified by the following analysis method.

Examples of the analysis method include iron and steel-atomic absorption spectrometry defined in JIS G 1257:2000, iron and steel-ICP emission spectrometry defined in JIS G 1258:2007, iron and steel-spark discharge emission spectrometry defined in JIS G 1253:2002, iron and steel-fluorescent X-ray spectrometry defined in JIS G 1256:1997, and gravimetric, titration and absorption spectrometric methods defined in JIS G 1211 to JIS G 1237.

Specific examples thereof include a solid emission spectrometer manufactured by SPECTRO, in particular, a spark discharge emission spectrometer, model: SPECTROLAB, type: LAVMB08A, or ICP apparatus CIROS120 type manufactured by Rigaku Corporation.

In particular, when specifying C (carbon) and S (sulfur), an infrared absorption method after combustion in a current of oxygen (combustion in high frequency induction furnace) defined in JIS G 1211:2011 is also used. Specific examples thereof include a carbon-sulfur analyzer CS-200 manufactured by LECO Corporation.

In particular, when N (nitrogen) and O (oxygen) are specified, methods for determination of nitrogen content for an iron and steel defined in JIS G 1228:1997 and general rules for determination of oxygen in metallic materials defined in JIS Z 2613:2006 are also used. Specific examples thereof include an oxygen-nitrogen analyzer, TC-300/EF-300 manufactured by LECO Corporation.

### 1.8. Application

Examples of applications of the amorphous alloy soft magnetic powder 100 include, in addition to the electromagnetic wave suppressor described above, a dust core, a magnetic fluid, and a magnetic head.

FIG. 2 is a cross-sectional view showing an example of a configuration of an electromagnetic wave suppressor 500.

The electromagnetic wave suppressor 500 shown in FIG. 2 includes the amorphous alloy soft magnetic powder 100 containing the flat particles 200, and a binding agent 400 that binds the flat particles 200 to each other. Various resin materials such as a thermoplastic resin and a thermosetting resin are used for the binding agent 400.

Examples of the thermoplastic resin include polyvinyl acetate, polyvinyl alcohol, polyvinyl butyral, polystyrene, an acrylonitrile butadiene styrene (ABS) resin, a methacrylic resin, a noryl resin, polyurethane, an ionomer resin, cellulose-based plastic, polyethylene, polypropylene, polyamide, polycarbonate, polyacetal, polyphenylene sulfide, polyvinylidene chloride, polyester, and a fluororesin.

Examples of the thermosetting resin include polyimide, an epoxy resin, a phenol resin, a urea resin, a melamine resin, a silicone resin, polyamide imide, benzocyclobutene, benzoxazine, and a cyanate resin.

A thermosetting resin and a thermoplastic resin may be used in combination.

A content rate of the amorphous alloy soft magnetic powder 100 in the electromagnetic wave suppressor 500 is not particularly limited, and is preferably 50 mass % or more and 95 mass % or less, and more preferably 60 mass % or more and 90 mass % or less. Accordingly, when a kneaded material containing the amorphous alloy soft magnetic powder 100 and the binding agent 400 is molded into a sheet shape, the coverage of the flat particles 200 can be sufficiently secured. The binding agent 400 binds the flat particles 200 to each other, and it is possible to sufficiently secure the mechanical properties of the electromagnetic wave suppressor 500.

A thickness of the electromagnetic wave suppressor 500 is appropriately set according to an application, and is preferably about 30 μm or more and 5 mm or less, and more preferably about 50 μm or more and 300 μm or less.

### 2. Method for Manufacturing Amorphous Alloy Soft Magnetic Powder

Next, a method for manufacturing an amorphous alloy soft magnetic powder according to the embodiment will be described.

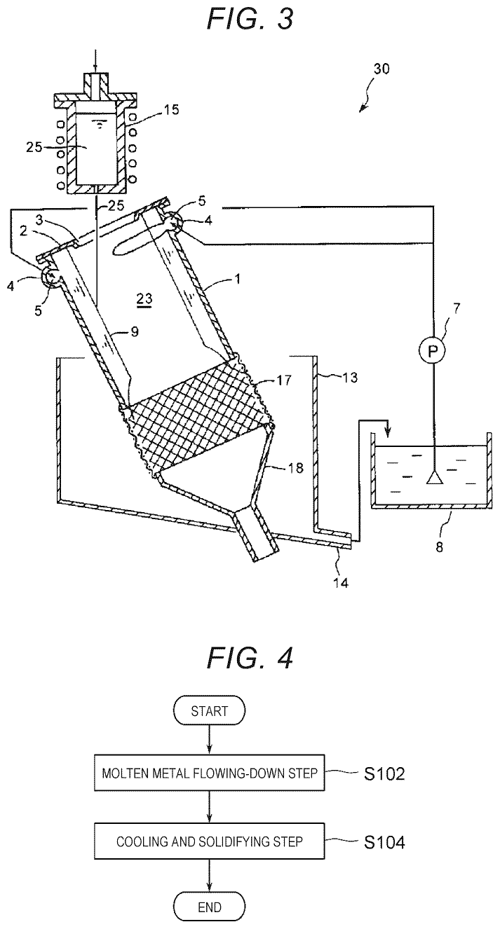

FIG. 3 is a cross-sectional view showing an example of a powder manufacturing device 30 used in the method for manufacturing an amorphous alloy soft magnetic powder according to the embodiment.

The powder manufacturing device 30 shown in FIG. 3 includes a cooling tubular body 1 (tubular body), a crucible 15 (molten metal supply portion), and a pump 7. The cooling tubular body 1 is a tubular body for forming a coolant layer 9 formed of a swirling flow of a coolant at an inner circumferential surface of the cooling tubular body 1. The crucible 15 is a supply container for a molten metal 25 to flow down and to be supplied to a space portion 23 inside the coolant layer 9. The pump 7 supplies the coolant to the cooling tubular body 1. The molten metal 25 is prepared according to a composition of the amorphous alloy soft magnetic powder to be manufactured.

The cooling tubular body 1 has a cylindrical shape, and is provided such that a tubular body axis line extends along a vertical direction or is inclined at an angle of 30° or less with respect to the vertical direction.

An upper end opening of the cooling tubular body 1 is closed by a lid body 2. An opening portion 3 for supplying the molten metal 25 flowing down to the space portion 23 of the cooling tubular body 1 is formed in the lid body 2.

A coolant injecting pipe 4 (coolant outflow portion) for injecting the coolant to the inner circumferential surface of the cooling tubular body 1 is provided at an upper portion of the cooling tubular body 1. A plurality of discharge ports 5 of the coolant injecting pipe 4 are provided at equal intervals along a circumferential direction of the cooling tubular body 1.

The coolant injecting pipe 4 is coupled to a tank 8 via pipes to which the pump 7 is coupled, and a coolant in the tank 8 sucked up by the pump 7 is injected and supplied via the coolant injecting pipe 4 into the cooling tubular body 1. Accordingly, the coolant gradually flows down while rotating along the inner circumferential surface of the cooling tubular body 1, and accordingly, the coolant layer 9 along the inner circumferential surface is formed. A cooler may be interposed as necessary in the tank 8 or in a middle of a circulation flow path. As the coolant, in addition to water, oil such as silicone oil is used, and various additives may be further added. By removing dissolved oxygen in the coolant in advance, oxidation of the manufactured powder can be reduced.

A cylindrical liquid draining mesh body 17 is continuously provided at a lower portion of the cooling tubular body 1. A funnel-shaped powder recovery container 18 is provided at a lower side of the liquid draining mesh body 17. A coolant recovery cover 13 is provided around the liquid draining mesh body 17 so as to cover the liquid draining mesh body 17. A drain port 14 formed in a bottom portion of the coolant recovery cover 13 is coupled via a pipe to the tank 8.

FIG. 4 is a flowchart showing a configuration of the method for manufacturing an amorphous alloy soft magnetic powder according to the embodiment.

The method for manufacturing an amorphous alloy soft magnetic powder shown in FIG. 4 is a method for manufacturing an amorphous alloy soft magnetic powder using the above powder manufacturing device 30, and includes a molten metal flowing-down step S102 and a cooling and solidifying step S104. Hereinafter, the steps will be sequentially described.

### 2.1. Molten Metal Flowing-Down Step

In the molten metal flowing-down step S102, the pump 7 is operated in advance to form the coolant layer 9 on the inner circumferential surface of the cooling tubular body 1. Next, the molten metal 25 is narrowed into a line from the crucible 15 (molten metal supply portion) to flow down into the space portion 23.

A diameter of the molten metal 25 flowing down from the crucible 15 is 1 mm or more and 10 mm or less, preferably 2 mm or more and 8 mm or less, and more preferably 3 mm or more and 6 mm or less. By setting the diameter of the molten metal 25 within the above range, an amount of the molten metal 25 flowing down for a certain period of time can be optimized, so that amorphization can be sufficiently achieved and manufacturing efficiency of the amorphous alloy soft magnetic powder 100 can be sufficiently increased.

### 2.2. Cooling and Solidifying Step

In the cooling and solidifying step S104, the molten metal 25 that flowed down directly enters the coolant layer 9, and is caught in the swirling coolant. Accordingly, the molten metal 25 is stretched flat and cooled and solidified to obtain particles such as the above flat particles 200. By allowing the molten metal 25 flowing down from the crucible 15 to directly enter the coolant layer 9 without being scattered by gas, the flat particles 200 are easily formed. The amorphous alloy soft magnetic powder 100 to be manufactured has a relatively large average particle diameter D. Further, the molten metal 25 that is not scattered is likely to be stretched flat by receiving an impact of a swirling flow.

Since the coolant layer 9 can stably maintain an extremely high cooling rate by continuously supplying the coolant, even when the average particle diameter D of the manufactured amorphous alloy soft magnetic powder 100 is large, amorphization can be achieved.

A flow speed of the coolant supplied to the cooling tubular body 1 during ejection is 50 m/sec or more and 150 m/sec or less, and preferably 75 m/sec or more and 125 m/sec or less. By setting the flow speed of the coolant within the above range, an action of stretching the molten metal 25 that enters the coolant layer 9 works, and the solidified particles become appropriately flat. A cooling rate of the molten metal 25 by the coolant can be sufficiently increased. The cooling rate of the molten metal 25 by the coolant layer 9 is preferably 10⁵ K/sec or more, and more preferably 10⁶ K/sec or more. Accordingly, even when the flat particles 200 have a large diameter, the amorphization can be achieved. As a result, the amorphous alloy soft magnetic powder 100 having the above average particle diameter and satisfying a high magnetic permeability and a low coercive force is obtained.

The particle diameter of the amorphous alloy soft magnetic powder 100 is reduced by, for example, reducing a downflow amount of the molten metal 25 flowing down from the crucible 15 and increasing the flow speed of the coolant during ejection. The particle diameter is increased by performing an opposite operation.

An aspect ratio of a particle shape of the amorphous alloy soft magnetic powder 100 is increased by, for example, reducing the downflow amount of the molten metal 25 or increasing the flow speed of the coolant during ejection. The aspect ratio is reduced by performing an opposite operation.

Further, by reducing the downflow amount or increasing the flow speed of the coolant, an amorphous degree of the amorphous alloy soft magnetic powder 100 can be increased, and a high magnetic permeability and a low coercive force can be achieved.

### 3. Effects of Embodiment

As described above, the amorphous alloy soft magnetic powder 100 according to the embodiment contains the particle having a flat shape, and has a volume-based average particle diameter of more than 150 μm and 500 μm or less measured by a laser diffraction and scattering particle size distribution analyzer, and a coercive force of 398 A/m or less (5.0 Oe or less).

According to such a configuration, it is possible to obtain the amorphous alloy soft magnetic powder 100 that can be manufactured into a sheet-shaped molded product having a high coverage without adding the amorphous alloy soft magnetic powder 100 at a high concentration. The particles having a flat shape (flat particles 200) increase the magnetic permeability of the molded product. Therefore, by using the amorphous alloy soft magnetic powder 100, it is possible to implement the electromagnetic wave suppressor 500 that is excellent in mechanical properties and also excellent in properties of suppressing electromagnetic waves.

In the amorphous alloy soft magnetic powder 100, a proportion of particles (−600/+300 particles) having a particle diameter of more than 300 μm and 600 μm or less classified by sieving is preferably 15 mass % or more and 40 mass % or less.

According to the amorphous alloy soft magnetic powder 100 in which the mass proportion of the −600/+300 particles is within the above range, it is possible to obtain a sheet-shaped molded product having a particularly high coverage of the flat particles 200 and a high magnetic permeability while further reducing the addition amount.

In the amorphous alloy soft magnetic powder 100, the coercive force of particles (−600/+300 particles) having a particle diameter of more than 300 μm and 600 μm or less classified by sieving is preferably 398 A/m or less (5.0 Oe or less).

When the coercive force of the −600/+300 particles is within the above range, the coercive force of the entire amorphous alloy soft magnetic powder 100 can be sufficiently reduced.

In the amorphous alloy soft magnetic powder 100, an aspect ratio of particles having a particle diameter of more than 150 μm and 212 μm or less classified by sieving is preferably 4 or more and 100 or less. The coercive force of particles having a particle diameter of more than 150 μm and 212 μm or less is preferably 159 A/m or less (2.0 Oe or less).

Such an amorphous alloy soft magnetic powder 100 can particularly increase the coverage (space factor) of the flat particles 200 without increasing the concentration of the amorphous alloy soft magnetic powder 100 added, and can implement the electromagnetic wave suppressor having particularly good properties of suppressing electromagnetic waves.

The method for manufacturing an amorphous alloy soft magnetic powder according to the embodiment is a method using the powder manufacturing device 30 including the crucible 15 (molten metal supply portion), the cooling tubular body 1 (tubular body), and the coolant injecting pipe 4 (coolant outflow portion). The crucible 15 allows the molten metal 25 to flow down. The cooling tubular body 1 is provided below the crucible 15. The coolant injecting pipe 4 causes the coolant to flow out along the inner circumferential surface of the cooling tubular body 1 to form a swirling flow.

The method for manufacturing an amorphous alloy soft magnetic powder includes the molten metal flowing-down step S102 and the cooling and solidifying step S104. In the molten metal flowing-down step S102, the molten metal 25 flows down from the crucible 15 while being narrowed to a diameter of 1 mm or more and 10 mm or less. In the cooling and solidifying step S104, the molten metal 25 that flows down enters a swirling flow at a speed of 50 m/sec or more and 150 m/sec or less without being scattered by gas to obtain the amorphous alloy soft magnetic powder 100.

The amorphous alloy soft magnetic powder 100 thus obtained contains the particle having a flat shape, and has a volume-based average particle diameter of more than 150 μm and 500 μm or less measured by a laser diffraction and scattering particle size distribution analyzer, and a coercive force of 398 A/m or less (5.0 Oe or less).

According to such a configuration, the amorphous alloy soft magnetic powder 100 containing particles having a flat shape and having a relatively large diameter and a low coercive force can be efficiently manufactured. By using such an amorphous alloy soft magnetic powder 100, a sheet-shaped molded product having a high coverage without being added at a high concentration can be manufactured. The particles having a flat shape (flat particles 200) increase the magnetic permeability of the molded product. Therefore, by using the amorphous alloy soft magnetic powder 100, it is possible to implement the electromagnetic wave suppressor 500 that is excellent in mechanical properties and also excellent in properties of suppressing electromagnetic waves.

Although the amorphous alloy soft magnetic powder and the method for manufacturing an amorphous alloy soft magnetic powder according to the present disclosure are described above based on the illustrated embodiment, the present disclosure is not limited thereto. For example, the amorphous alloy soft magnetic powder according to the present disclosure may be obtained by adding any constituent to the above embodiment.

### EXAMPLES

Next, specific Examples of the present disclosure will be described.

### 4. Manufacturing Amorphous Alloy Soft Magnetic Powder 4.1. Sample No. 1

First, a raw material was melted in a high-frequency induction furnace, and powdered using the powder manufacturing device shown in FIG. 3 to obtain a metal powder. At this time, a diameter of the molten metal flowing down from the crucible was 5 mm, and an outflow rate of a coolant was 100 m/sec.

Next, the manufactured metal powder was put into a sieve for JIS test having a nominal size of opening of 600 μm, and a classified material (−600 particles) that passed through the sieve was collected. The collected −600 particles were used as the amorphous alloy soft magnetic powder. A constituent material for the obtained amorphous alloy soft magnetic powder has a composition represented by the compositional formula (Fe₁₋ₓCrₓ)ₐ(Si_{1-y}B_{y})_{100-a-b}C_{b}(x=0.03, y=0.5, a=76.0, b=2.0) according to an atomic ratio. This compositional formula can be rewritten as Fe_{73.72}Cr_{2.28}Si₁₁B₁₁C₂.

An average particle diameter, aspect ratio, and coercive force of the entire amorphous alloy soft magnetic powder, a mass proportion and coercive force of −600/+300 particles, a mass proportion and coercive force of −300/+212 particles, a mass proportion, aspect ratio, and coercive force of −212/+150 particles, and a mass proportion and coercive force of −150 particles were measured and calculated. Measurement results and calculation results are shown in Table 1.

### 4.2. Sample Nos. 2 to 10

An amorphous alloy soft magnetic powder was obtained in the same manner as in Sample No. 1 except that manufacturing conditions were changed such that the amorphous alloy soft magnetic powder had a configuration shown in Table 1.

### 4.3. Sample No. 11

An amorphous alloy soft magnetic powder was obtained in the same manner as in Sample No. 1 except that the metal powder was obtained using a powder manufacturing device in the related art and classified.

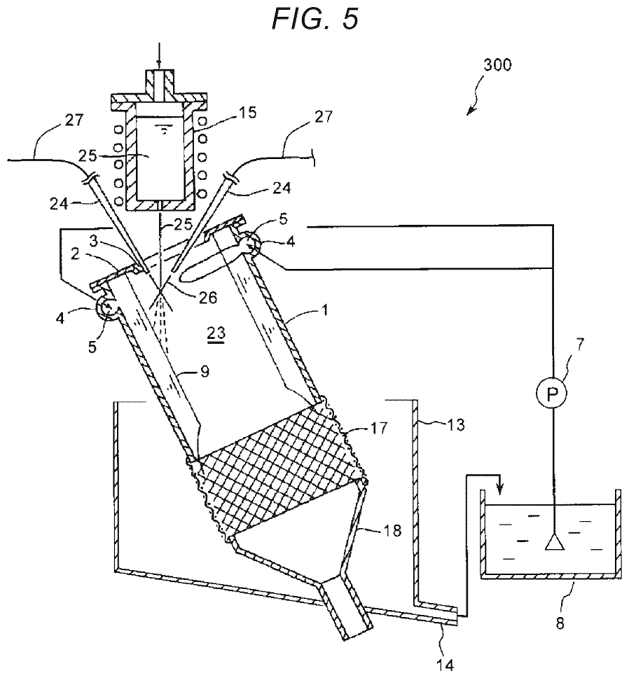

FIG. 5 is a cross-sectional view showing a powder manufacturing device 300 in the related art. In FIG. 5, the same components as those shown in FIG. 3 are denoted by the same reference signs.

The powder manufacturing device 300 in the related art shown in FIG. 5 is obtained by adding, to the powder manufacturing device 30 shown in FIG. 3, a mechanism for scattering the molten metal 25 by a gas jet 26. The gas jet 26 is supplied from a jet nozzle 24 coupled to a gas supply pipe 27 to the space portion 23.

### 4.4. Sample No. 12

An amorphous alloy soft magnetic powder was obtained in the same manner as in Sample No. 1, except that after the metal powder was obtained using the powder manufacturing device in the related art, particles were flattened using a ball mill and then classified.

In Table 1, among the amorphous alloy soft magnetic powders in the Sample Nos., amorphous alloy soft magnetic powders corresponding to the present disclosure are shown as “Examples”, and amorphous alloy soft magnetic powders not corresponding to the present disclosure are shown as “Comparative Examples”.

### 5. Evaluation of Amorphous Alloy Soft Magnetic Powder 5.1. Coverage of Flat Particles

The amorphous alloy soft magnetic powder in each of Examples and Comparative Examples was kneaded with a transparent resin and an organic solvent to obtain a kneaded material. The obtained kneaded material was applied in the form of a sheet to prepare a test piece simulating an electromagnetic wave suppressor.

Next, the obtained test piece was observed, and a coverage of the amorphous alloy soft magnetic powder was measured based on an observed image. Then, the measured coverage was evaluated in accordance with the following evaluation criteria. Evaluation results are shown in Table 1.
A: The coverage is high.
B: The coverage is slightly high.
C: The coverage is slightly low.
D: The coverage is low.

### 5.2. Magnetic Permeability of Amorphous Alloy Soft Magnetic Powder

A magnetic permeability of the amorphous alloy soft magnetic powder in each of Examples and Comparative Examples was measured by the following procedure. If a magnetic permeability of the amorphous alloy soft magnetic powder is high, a magnetic permeability of the electromagnetic wave suppressor tends to be high. Therefore, the magnetic permeability of the powder was evaluated.

First, the amorphous alloy soft magnetic powder, an epoxy resin as the binding agent, and toluene as the organic solvent were mixed to obtain a mixture. An addition amount of the epoxy resin was 2 parts by mass with respect to 100 parts by mass of the amorphous alloy soft magnetic powder.

Next, the obtained mixture was stirred and then dried for a short time to obtain a massive dried body. Next, the dried body was sieved with a sieve having an opening of 400 μm, the dried body was pulverized, and granulated powders were obtained. The obtained granulated powders were dried at 50° C. for 1 hour.

Next, a mold is filled with the obtained granulated powders, and a molded product was obtained based on the following molding conditions.
Molding method: press molding
Shape of molded product: ring shape
Dimensions of molded product: outer diameter 14 mm, inner diameter 8 mm, thickness 3 mm
Molding pressure: 3 t/cm² (294 MPa)

Next, the molded product was heated in an air atmosphere at a temperature of 150° C. for 0.50 hour to cure the binding agent. Accordingly, a dust core was obtained.

A magnetic element was prepared based on the following preparation conditions using the obtained dust core.
Constituent material for conductive wire: Cu
Wire diameter of conductive wire: 0.6 mm
Winding number (during measurement of magnetic permeability): 7 turns
Winding number (during measurement of core loss): 36 turns on primary side and 36 turns on secondary side

Next, a magnetic permeability of the prepared magnetic element was measured at a frequency of 100 kHz using an impedance analyzer. The obtained magnetic permeability was evaluated in accordance with the following evaluation criteria. Evaluation results are shown in Table 1.
A: The magnetic permeability is high.
B: The magnetic permeability is slightly high.
C: The magnetic permeability is slightly low.
D: The magnetic permeability is low.

TABLE 1

| | | | Configuration of amorphous alloy soft magnetic powder | | | | | | | |
|---|---|---|---|---|---|---|---|---|---|---|
| | | | Average | | | | −600/+300 particle | | | −300/+212 particles |
| | | | particle | Aspect | Coercive | | Mass | Coercive | | Mass |
| Sample | | Manufacturing | diameter | ratio | force | | proportion | force | | proportion |
| No. | Category | Method | μm | — | A/m | Oe | mass % | A/m | Oe | mass % |
| 1 | Example | Rotating | 222 | 6 | 72 | 0.9 | 20 | 64 | 0.8 | 25 |
| 2 | Example | water flow | 241 | 15 | 80 | 1.0 | 25 | 80 | 1.0 | 25 |
| 2 | Example | (no | 254 | 15 | 95 | 1.2 | 30 | 80 | 1.0 | 25 |
| 4 | Example | scattering | 258 | 20 | 119 | 1.5 | 30 | 119 | 1.5 | 30 |
| 5 | Example | by gas) | 286 | 25 | 159 | 2.0 | 35 | 159 | 2.0 | 35 |
| 6 | Example | | 301 | 30 | 199 | 2.5 | 40 | 199 | 2.5 | 30 |
| 7 | Example | | 184 | 5 | 159 | 2.0 | 10 | 159 | 2.0 | 25 |
| 8 | Example | | 301 | 35 | 239 | 3.0 | 45 | 239 | 3.0 | 20 |
| 9 | Example | | 241 | 15 | 398 | 5.0 | 25 | 318 | 4.0 | 25 |
| 10 | Comparative | Rotating | 241 | 15 | 477 | 6.0 | 25 | 637 | 8.0 | 25 |
| | Example | water flow | | | | | | | | |
| | | (no | | | | | | | | |
| | | scattering | | | | | | | | |
| | | by gas) | | | | | | | | |
| 11 | Comparative | Rotating | 20 | 2 | 64 | 0.8 | 0 | — | — | 0 |
| | Example | water flow | | | | | | | | |
| | | (scattered | | | | | | | | |
| | | by gas) | | | | | | | | |
| 12 | Comparative | Rotating | 520 | 200 | 2387 | 30 | 5 | 2387 | 30 | 30 |
| | Example | water flow | | | | | | | | |
| | | and ball | | | | | | | | |
| | | mill | | | | | | | | |

| | Configuration of amorphous alloy soft magnetic powder | | | | | | | | | | |
|---|---|---|---|---|---|---|---|---|---|---|---|
| | −300/+212 particles | | −212/+150 particles | | | | −150 particles | | | Evaluation result | |
| | Coercive | | Mass | Aspect | Coercive | | Mass | Coercive | | | Magnetic |
| Sample | force | | proportion | ratio | force | | proportion | force | | Coverage | permeability |
| No. | A/m | Oe | mass % | — | A/m | Oe | mass % | A/m | Oe | — | — |
| 1 | 16 | 0.2 | 25 | 10 | 16 | 0.2 | 30 | 16 | 0.2 | B | A |
| 2 | 16 | 0.2 | 25 | 20 | 16 | 0.2 | 25 | 16 | 0.2 | A | A |
| 2 | 16 | 0.2 | 20 | 20 | 16 | 0.2 | 25 | 16 | 0.2 | A | A |
| 4 | 24 | 0.3 | 15 | 25 | 24 | 0.3 | 25 | 24 | 0.3 | A | A |
| 5 | 40 | 0.5 | 15 | 25 | 40 | 0.5 | 15 | 40 | 0.5 | A | A |
| 6 | 56 | 0.7 | 20 | 25 | 56 | 0.7 | 10 | 56 | 0.7 | A | B |
| 7 | 40 | 0.5 | 25 | 25 | 40 | 0.5 | 40 | 40 | 0.5 | C | A |
| 8 | 80 | 1.0 | 20 | 25 | 80 | 1.0 | 15 | 80 | 1.0 | B | B |
| 9 | 279 | 3.5 | 25 | 35 | 239 | 3.0 | 25 | 159 | 2.0 | A | C |
| 10 | 127 | 1.6 | 25 | 20 | 127 | 1.6 | 25 | 127 | 1.6 | A | D |
| 11 | — | — | 0 | — | — | — | 100 | 64 | 0.8 | D | A |
| 12 | 2387 | 30 | 50 | 200 | 2387 | 30 | 15 | 2387 | 30 | D | D |

As is clear from Table 1, in the amorphous alloy soft magnetic powder in each of Examples, when the amorphous alloy soft magnetic powder was kneaded together with the binding agent and molded into a sheet shape, a high coverage of the flat particles could be secured. On the other hand, the amorphous alloy soft magnetic powders in some of Comparative Examples had an insufficient coverage.

It was also recognized that the magnetic permeability of the amorphous alloy soft magnetic powder in Examples was sufficiently higher than that of the amorphous alloy soft magnetic powder in some Comparative Examples.

From the above description, it has been recognized that by using the amorphous alloy soft magnetic powder according to the present disclosure, a molded product having a high coverage of the flat particles and a high magnetic permeability without adding the amorphous alloy soft magnetic powder at a high concentration can be manufactured.

What is claimed is:

1. An amorphous alloy soft magnetic powder comprising:
a particle having a flat shape, wherein
the amorphous alloy soft magnetic powder has a volume-based average particle diameter of more than 150 μm and 500 μm or less measured by a laser diffraction and scattering particle size distribution analyzer, and a coercive force of 398 A/m or less, i.e., 5.0 Oe or less.

2. The amorphous alloy soft magnetic powder according to claim 1, wherein
a proportion of particles having a particle diameter of more than 300 μm and 600 μm or less classified by sieving is 15 mass % or more and 40 mass % or less.

3. The amorphous alloy soft magnetic powder according to claim 1, wherein
a coercive force of particles having a particle diameter of more than 300 μm and 600 μm or less classified by sieving is 398 A/m or less, i.e., 5.0 Oe or less.

4. The amorphous alloy soft magnetic powder according to claim 1, wherein
an aspect ratio of particles having a particle diameter of more than 150 μm and 212 μm or less classified by sieving is 4 or more and 100 or less, and
a coercive force of the particles having a particle diameter of more than 150 μm and 212 μm or less is 159 A/m or less, i.e., 2.0 Oe or less.

5. A method for manufacturing an amorphous alloy soft magnetic powder using a device including
a molten metal supply portion that causes a molten metal to flow down,
a tubular body provided below the molten metal supply portion, and
a coolant outflow portion that causes a coolant to flow out along an inner circumferential surface of the tubular body to form a swirling flow,
the method for manufacturing an amorphous alloy soft magnetic powder comprising:
causing the molten metal to flow down from the molten metal supply portion while narrowing the molten metal to a diameter of 1 mm or more and 10 mm or less; and
causing the molten metal that flows down to enter the swirling flow at a speed of 50 m/sec or more and 150 m/sec or less without being scattered by gas to obtain an amorphous alloy soft magnetic powder, wherein
the amorphous alloy soft magnetic powder,
contains a particle having a flat shape,
has a volume-based average particle diameter of more than 150 μm and 500 μm or less measured by a laser diffraction and scattering particle size distribution analyzer, and
has a coercive force of 398 A/m or less, i.e., 5.0 Oe or less.
